(19) United States
(12) Patent Application Publication
(10) Pub. No.: US 2022/0199395 A1
(43) Pub. Date: Jun. 23, 2022

(54) OPTIMIZING GROWTH METHOD FOR IMPROVING QUALITY OF MOCVD EPITAXIAL THIN FILMS

(71) Applicant: Wenzhou University, Zhejiang (CN)

(72) Inventor: Rong Zhong, Zhejiang (CN)

(73) Assignee: Wenzhou University, Zhejiang (CN)

(21) Appl. No.: 17/411,025

(22) Filed: Aug. 24, 2021

(30) Foreign Application Priority Data
Dec. 22, 2020 (CN) 202011524321.3

(51) Int. Cl. H01L 21/02

(52) U.S. Cl. CPC H01L 21/0254; H01L 21/02661; H01L 21/0262; H01L 21/02458; H01L 21/02381

(57) ABSTRACT

The present invention provides an optimizing growth method for improving quality of MOCVD epitaxial thin films, including the following method: step 1, putting a substrate and a thin film A to a reaction chamber of an MOCVD equipment; and feeding a compound containing an element X as an X source under the condition that the reaction chamber is filled with H2; configuring a temperature, reaction chamber pressure and deposition time within a parameter range where the gaseous compound can decompose X atoms; pre-depositing an X atomic layer on a surface of the substrate or the thin film A; the X atomic layer is adsorbed on the substrate or thin film A at this time; and the X atomic layer can be reacted with other compounds to generate a thin film B component in the follow-up process, or can directly form a thin film B component with the thin film A.

### CROSS-REFERENCE TO RELATED APPLICATION

The present application is based on and claims the priority benefits of China application No. 202011524321.3, filed on Dec. 22, 2020. The entirety of the above-mentioned patent application is hereby incorporated by reference herein and made a part of this specification.

### BACKGROUND

### Technical Field

The present invention relates to the technical field of semiconductor film materials, and mainly relates to an optimizing growth method for improving quality of an MOCVD epitaxial thin film.

### Description of Related Art

Researches and applications on III-V nitride materials are leading topics and hot spots in the field of semiconductors in today's world. The most typical representative in III-V nitride materials is GaN materials. Due to the characteristics of wide forbidden bandwidth, stable chemical properties, high electronic mobility and good heat-conducting property, GaN materials can be widely applied in the preparation of opto-semiconductors, high-mobility semiconductors and other devices.

Currently, the common substrate materials on the market are sapphire, SiC, Si, AlN, and the like. At present, sapphire substrate is the most widely used material having the maturest technology. But, sapphire substrate has poor thermal diffusivity and higher cost, and has difficulties in the large-size growth of GaN thin films. SiC substrate is highly matched with GaN materials in each property, but has high cost; therefore, SiC substrate is used in some special cost-ignoring fields. There are lots of advantages in epitaxial growth of GaN thin films on a Si substrate, for example, the Si substrate is a typical semiconductor material, and has a very matured manufacturing process, large size, low price and other advantages. But there are large lattice constant difference (17%) and difference of coefficient of thermal expansion (56%) between GaN and Si, such that it is very difficult to prepare a high-quality GaN thin film on a Si substrate. At present, the method for epitaxial growth of GaN thin films on a Si substrate includes AlN/AlGaN multi-buffer layer structure, low-temperature AlN (LT-AlN) inserting layer technology, graphic substrate technology, and an Al(Ga)N/GaN superlattice structure; but the above methods used for epitaxial growth of GaN thin films have relatively complex growth process and thus, can be achieved difficultly. AlN is a kind of ideal substrate material, and needs to be obtained by a heteroepitaxy method. Currently, there is no matured practical epitaxial technology based on an AlN substrate.

When MOCVD is used for epitaxial growth of a GaN thin film, a plurality of buffer layers (for example, AlN, AlGaN and other thin films) must be subjected to epitaxial growth no matter what substrate is used, and finally, a GaN thin film is subjected to epitaxial growth on the buffer layers. During the process of being in transition to a buffer layer from a substrate (for example, an AlN thin film is grown on a Si substrate), to a buffer layer having another component from a buffer layer having one component (for example, an AlGaN thin film is grown on an AlN thin film, and an Al_{y}Ga_{1-y}N thin film is grown on an AlₓGa₁₋ₓN thin film), to a GaN thin film from a buffer layer (for example, an AlGaN thin film is grown on an AlGaN thin film), and the like, as long as the component of the thin film changes, it is likely to cause the formation of cracks and flaws on the surface of the thin film due to the existence of internal stress, interface bonding strength and the like, thus influencing the quality of the thin film. There are lots of methods to improve the surface quality of a thin film, for example, internal stress may be regulated by the optimized design of an epitaxy structure; internal stress may be eased by optimizing process growth parameters of each layer of thin film; internal stress may be eliminated or eased by heat treatment annealing, tempering and other methods, and interface bonding strength is enhanced and the like. According to the nucleation growth theory of a thin film and the characteristics of MOCVD epitaxial growth, the patent proposes a novel optimization method for epitaxial growth of a thin film with various kinds of buffer layers (AlN, AlGaN, and the like) and a GaN thin film as objects, thus achieving the purpose of enhancing interface bonding strength between different thin films.

### SUMMARY

The technical problem to be solved by the present invention is to provide an optimizing growth method for improving quality of MOCVD epitaxial thin films by using a pre-deposited nucleation layer.

The optimizing growth method for improving quality of an MOCVD epitaxial thin film includes the following steps:

step 1, putting a substrate and a thin film A to a reaction chamber of an MOCVD equipment; and feeding a compound containing an element X as an X source under the condition that the reaction chamber is filled with H₂; configuring a temperature, reaction chamber pressure and deposition time within a parameter scope where the gaseous compound can decompose X atoms; pre-depositing an X atomic layer on a surface of the substrate or the thin film A, wherein the X atomic layer is adsorbed on the substrate or thin film A at this time; and the X atomic layer can be reacted with other compounds to generate a thin film B component in the follow-up process, or directly form a thin film B component with the thin film A;

step 2, after completing the growth of the above pre-deposited X atomic layer, and subjecting the thin film B to growth; simultaneously feeding all gaseous compounds required by epitaxial growth of the thin film B under the condition that the reaction chamber is filled with H₂; configuring a temperature, reaction chamber pressure and deposition time within a parameter range capable of achieving epitaxial growth of the thin film; subjecting the film B to epitaxial growth on the X atomic layer, wherein the pre-deposited X atomic layer is firstly reacted with the gas during the process, thus providing nucleation sites for the thin film B, and then the thin film B grows up with these nucleation sites as starting points; or wherein the pre-deposited X atomic layer has generated a thin film B component with the thin film A as nucleation sites; and at this time, the thin film B grows up with these nucleation sites as starting points; during such growing process, the pre-deposited X atomic layer disappears and becomes a portion of the thin film B.

Preferably, in the step 1, the temperature is controlled within a range from 800° C. to 1400° C.; the reaction chamber pressure is controlled within a range from 20 mbar to 200 mbar; and the time is controlled within a range from 0 s to 300 s.

Preferably, the optimizing growth method is characterized by:

subjecting an AlN buffer layer and a GaN thin film to epitaxial growth on a Si substrate, comprising the following preparation method:

(1) pretreating the Si substrate, includes a cleaning process and a desorption process;

(2) pre-depositing an Al atomic layer: putting the Si substrate to a reaction chamber of the MOCVD equipment, feeding TMAl as an Al source under the condition that the reaction chamber is filled with H₂; wherein a surface temperature of the Si substrate is controlled within a range from 800° C. to 1400° C., a reaction chamber pressure is controlled within a range from 20 mbar to 200 mbar; and time is controlled within a range from 0 s to 300 s, thus obtaining a pre-deposited Al atomic layer, where the pre-deposited Al atomic layer is adsorbed on the Si substrate;

(3) growing the AlN buffer layer, feeding TMAl as an Al source and feeding NH₃ as a N source under the condition that the reaction chamber is filled with H₂; where during such process, the pre-deposited Al atomic layer is firstly reacted with NH₃ to form AlN nucleation sites, then AlN nucleation sites grow up to thereby forming an AlN thin film, and during such growing process, the pre-deposited Al atomic layer disappears and becomes a portion of the AlN thin film;

(4) growing a GaN epitaxial layer, feeding TMGa as a Ga source and feeding NH₃ as a N source under the condition that the reaction chamber is filled with H₂.

Preferably, the optimizing growth method is characterized by:

subjecting an AlGaN buffer layer and a GaN thin film to epitaxial growth on an AlN thin film, including the following preparation method:

(1) growing an AlN epitaxial layer on the Si substrate, feeding TMAl as an Al source and feeding NH₃ as a N source under the condition that the reaction chamber is filled with H₂;

(2) pre-depositing a Ga atomic layer: putting the AlN thin film to a chamber, feeding TMGa as a Ga source under the condition that the reaction chamber is filled with H₂; wherein a surface temperature of AlN is controlled within a range from 800° C. to 1400° C., a reaction chamber pressure is controlled within a range from 20 mbar to 200 mbar; and time is controlled within a range from 0 s to 300 s, thus obtaining a pre-deposited Ga atomic layer, where the pre-deposited Ga atomic layer is adsorbed on the AlN thin film to from AlGaN nucleation sites;

(3) growing an AlGaN buffer layer, feeding TMAl as an Al source, feeding TMGa as a Ga source, and feeding NH₃ as a N source under the condition that the reaction chamber is filled with H₂; where during such process, the pre-deposited AlGaN nucleation sites grow up to thereby forming an AlGaN thin film, and during such growing process, the pre-deposited Ga atomic layer disappears and becomes a portion of the AlGaN thin film;

(4) growing a GaN epitaxial layer, feeding TMGa as a Ga source and feeding NH₃ as a N source under the condition that the reaction chamber is filled with H₂.

Preferably, the optimizing growth method is characterized by:

subjecting an Al_{y}Ga_{1-y}N buffer layer and a GaN thin film to epitaxial growth on an AlₓGa₁₋ₓN thin film, including the following preparation method, wherein 1>x>y>0:

(1) growing AlN and Al_{0.45}Ga_{0.55}N epitaxial layers on a Si substrate, feeding TMAl as an Al source, feeding TMGa as a Ga source, and feeding NH₃ as a N source under the condition that the reaction chamber is filled with H₂;

(2) pre-depositing a Ga atomic layer, putting the Al_{0.45}Ga_{0.55}N thin film to a chamber, feeding TMGa as a Ga source under the condition that the reaction chamber is filled with H₂; where a surface temperature of Al_{0.45}Ga_{0.55}N is controlled within a range from 800° C. to 1400° C., a reaction chamber pressure is controlled within a range from 20 mbar to 200 mbar; and time is controlled within a range from 0 s to 300 s, thus obtaining a pre-deposited Ga atomic layer; where the pre-deposited Ga atomic layer can be adsorbed on the Al_{0.45}Ga_{0.55}N thin film, thus rendering the components thereof to be gradually close to an Al_{0.25}Ga_{0.75}N-grown thin film;

(3) growing an Al_{0.25}Ga_{0.75}N buffer layer, feeding TMAl as an Al source, feeding TMGa as a Ga source and feeding NH₃ as a N source under the condition that the reaction chamber is filled with H₂; during such process, a surface of the Al_{0.45}Ga_{0.55}N thin film contains more and more Ga component, such that the component thereof are closer and closer to the Al_{0.25}Ga_{0.75}N-grown thin film, thereby finally forming a stable Al_{0.25}Ga_{0.75}N grown thin film; wherein during such growing process, the pre-deposited Ga atomic layer disappears and becomes a transition portion grown with two thin films of Al_{0.45}Ga_{0.55}N and Al_{0.25}Ga_{0.75}N;

(4) growing a GaN epitaxial layer, feeding TMGa as a Ga source and feeding NH₃ as a N source under the condition that the reaction chamber is filled with H₂.

Preferably, the optimizing growth method is characterized by:

subjecting a GaN thin film to epitaxial growth on an AlGaN thin film, including the following preparation method:

(1) growing AlN and AlGaN epitaxial layers on a Si substrate, feeding TMAl as an Al source, feeding TMGa as a Ga source, and feeding NH₃ as a N source under the condition that the reaction chamber is filled with H₂;

(2) pre-depositing a Ga atomic layer, putting an AlGaN thin film to a chamber, feeding TMGa as a Ga source under the condition that the reaction chamber is filled with H₂; where a surface temperature of AlGaN is controlled within a range from 800° C. to 1400° C., a reaction chamber pressure is controlled within a range from 20 mbar to 200 mbar; and time is controlled within a range from 0 s to 300 s; where the pre-deposited Ga atomic layer can be adsorbed on the AlGaN thin film to form an AlGaN atomic layer with a higher component and reach a saturation point rapidly, thereby abstracting N atoms and forming GaN nucleation sites;

(3) growing a GaN buffer layer, feeding TMGa as a Ga source, and feeding NH₃ as a N source under the condition that the reaction chamber is filled with H₂; where during such process, the pre-deposited GaN nucleation sites grow up, thereby forming a GaN thin film, and during such growing process, the pre-deposited Ga atomic layer disappears and becomes a portion of the GaN thin film.

The optimizing growth method for improving the quality of an MOCVD epitaxial thin film with a pre-deposited nucleation layer has the following advantages: according to the characteristics of MOCVD epitaxial growth, the invention proposes a novel optimization method for epitaxial growth of a thin film with various kinds of buffer layers (AlN, AlGaN, and the like) and a GaN thin film as objects, thus achieving the purpose of enhancing interface bonding strength between different thin films. Thereby, the method can epitaxially grow AlN, AlGaN, GaN, and thin films having good homogeneity, high quality, less crack or crack free.

### BRIEF DESCRIPTION OF THE DRAWINGS

FIG. 1 is a structure diagram of a method for MOCVD epitaxial growth of a thin film, where (a) denotes a conventional method; and (b) denotes an optimization method.

FIG. 2 is a diagram showing a growth process of MOCVD epitaxial growth of a thin film in the conventional method.

FIG. 3 is a diagram showing a growth process of MOCVD epitaxial growth of a thin film in the optimization method.

FIG. 4 shows OM pictures of a GaN thin film grown on an AlN buffer layer prepared by different methods, where (a) denotes that there is no pre-deposited Al atomic layer; and (b) denotes that there is a pre-deposited Al atomic layer.

FIG. 5 shows AFM pictures of a GaN thin film grown on an AlN buffer layer prepared by different methods, where (a) denotes that there is no pre-deposited Al atomic layer; and (b) denotes that there is a pre-deposited Al atomic layer.

FIG. 6 shows intensity of an XRD swing curve of a GaN (0002) surface grown on an AlN buffer layer prepared by different methods.

FIG. 7 shows OM pictures of a GaN thin film grown on an AlGaN buffer layer prepared by different methods, where (a) denotes that there is no pre-deposited Ga atomic layer; and (b) denotes that there is a pre-deposited Ga atomic layer.

FIG. 8 shows AFM pictures of a GaN thin film grown on an AlGaN buffer layer prepared by different methods, where (a) denotes that there is no pre-deposited Ga atomic layer; and (b) denotes that there is a pre-deposited Ga atomic layer.

FIG. 9 shows intensity of an XRD swing curve of a GaN (0002) surface grown on an AlGaN buffer layer prepared by different methods.

FIG. 10 shows OM pictures of a GaN thin film grown on an Al_{0.25}Ga_{0.75}N buffer layer prepared on Al_{0.45}Ga_{0.55}N by different methods, where (a) denotes that there is no pre-deposited Ga atomic layer; and (b) denotes that there is a pre-deposited Ga atomic layer.

FIG. 11 shows AFM pictures of a GaN thin film grown on an Al_{0.25}Ga_{0.75}N buffer layer prepared on Al_{0.45}Ga_{0.55}N by different methods, where (a) denotes that there is no pre-deposited Ga atomic layer; and (b) denotes that there is a pre-deposited Ga atomic layer.

FIG. 12 shows intensity of an XRD swing curve of a GaN (0002) surface grown on an Al_{0.25}Ga_{0.75}N buffer layer prepared on Al_{0.45}Ga_{0.55}N by different methods.

FIG. 13 shows OM pictures of a GaN thin film when GaN is prepared on AlGaN by different methods, where (a) denotes that there is no pre-deposited Ga atomic layer; and (b) denotes that there is a pre-deposited Ga atomic layer.

FIG. 14 shows AFM pictures of a GaN thin film when GaN is prepared on AlGaN by different methods, where (a) denotes that there is no pre-deposited Ga atomic layer; and (b) denotes that there is a pre-deposited Ga atomic layer.

FIG. 15 shows intensity of an XRD swing curve of a corresponding GaN (0002) surface when GaN is prepared on AlGaN by different methods.

### DESCRIPTION OF THE EMBODIMENTS

### Embodiment 1

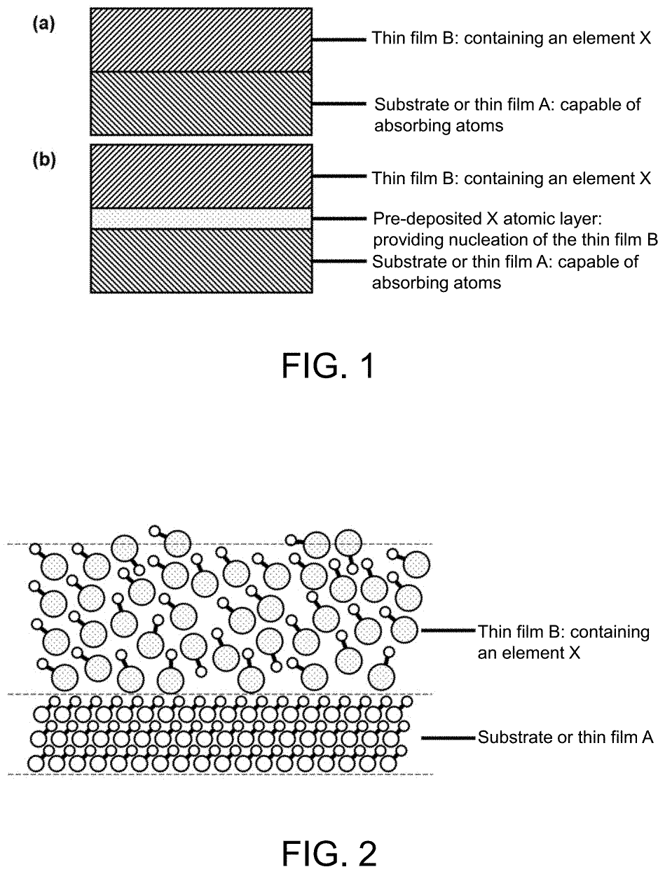

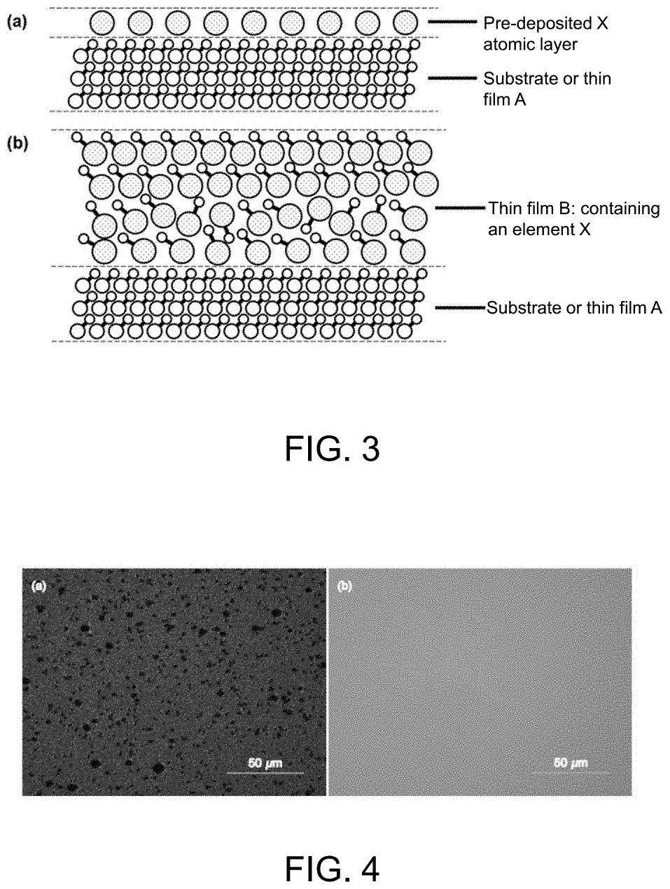

By referring to FIGS. 1-3, the optimizing growth method for improving quality of an MOCVD epitaxial thin film by a pre-deposited nucleation layer has an optimized structure as shown in FIG. 1(b). A preparation method of growing a thin film B on a substrate or a thin film A (as shown in FIG. 3) has the following steps:

step 1, pre-depositing an X atomic layer: a substrate or a thin film A was put to a reaction chamber of an MOCVD equipment; and a compound containing an element X was fed as an X source under the condition that the reaction chamber was filled with H₂; a temperature, reaction chamber pressure and deposition time were configured within a parameter range where the gaseous compound could decompose X atoms; an X atomic layer was pre-deposited on a surface of the substrate or the thin film A, where the X atomic layer was adsorbed on the substrate or thin film A; and the X atomic layer can be reacted with other compounds to generate a thin film B component in the follow-up process, or directly formed a thin film B component with the thin film A;

step 2, growing a thin film B: after completing the growth of the above pre-deposited X atomic layer, the thin film B was grown; all gaseous compounds required by epitaxial growth of the thin film B were fed simultaneously under the condition that the reaction chamber was filled with H₂ (for example, NH₃ was fed as a N source; TMX was fed as an X source; TMY was fed as a Y source; and TMZ was fed as a Z source); a temperature, reaction chamber pressure and deposition time were configured within a parameter range capable of achieving epitaxial growth of the thin film B; the thin film B was subjected to epitaxial growth on the X atomic layer, where the pre-deposited X atomic layer was firstly reacted with the gas during the process, thus providing nucleation sites for the thin film B, and then the thin film B grew up with these nucleation sites as starting points; or where the pre-deposited X atomic layer had generated a thin film B component with the thin film A as nucleation sites; and at this time, the thin film B grew up with these nucleation sites as starting points; during such growing process, the pre-deposited X atomic layer disappeared and became a portion of the thin film B. The obtained structure was shown in FIG. 3(b).

Preferably, in the step 1, the temperature was controlled within a range from 800° C. to 1400° C.; the reaction chamber pressure was controlled within a range from 20 mbar to 200 mbar; and the time was controlled within a range from 0 s to 300 s.

### EXAMPLE 2

By referring to FIGS. 4-6, an AlN buffer layer and a GaN thin film were subjected to epitaxial growth on a Si substrate, and the GaN thin film was represented and analyzed by an optical microscope (OM), an atomic force microscope (AFM), and an x-ray diffraction (XRD), thus judging the effect of the optimization method.

A preparation method for growing AlN and GaN thin films on a Si substrate has the following steps.

Step 1, pretreating the Si substrate: including a cleaning process and a desorption process (growth parameters are common knowledge in the art, and thus are not specified any more).

Step 2 pre-depositing an Al atomic layer: the Si substrate was put to a chamber, TMAl was fed as an Al source under the condition that the reaction chamber was filled with H₂; where a surface temperature of the Si substrate was controlled within a range from 800° C. to 1400° C., a reaction chamber pressure was controlled within a range from 20 mbar to 200 mbar; and time was controlled within a range from 0 s to 300 s, thus obtaining a pre-deposited Al atomic layer. The pre-deposited Al atomic layer might be adsorbed on the Si substrate.

Step 3, growing an AlN buffer layer (growth parameters are common knowledge in the art, and thus are not specified any more): TMAl was fed as an Al source and NH₃ was fed as a N source under the condition that the reaction chamber was filled with H₂. During such process, the pre-deposited Al layer was firstly reacted with NH₃ to form AlN nucleation sites, and the AlN nucleation sites grew up, thus forming an AlN thin film. During such growing process, the pre-deposited Al layer disappeared and became a portion of the AlN thin film.

Step 4, growing a GaN epitaxial layer (growth parameters are common knowledge in the art, and thus are not specified any more): TMGa was fed as a Ga source and NH₃ was fed as a N source under the condition that the reaction chamber was filled with H₂.

The present invention was further proved by contrastive analysis on the conventional method and optimization method to have the following beneficial effects below.

After an AlN buffer layer was grown by two methods of a conventional method (a pre-deposited Al atomic layer was not taken) and an optimization method (a pre-deposited Al atomic layer was taken), by making a comparison to the GaN thin film grown on the AlN buffer layer, it was found that the AlN buffer layer prepared by the optimization method greatly improved the homogeneity and crystal quality of the GaN thin film thereon.

It was found (FIG. 4) through OM observation that the GaN thin film grown by the conventional method showed a large number of holes and flaws; while the GaN thin film grown by the optimization method was smooth, and cracks could be found.

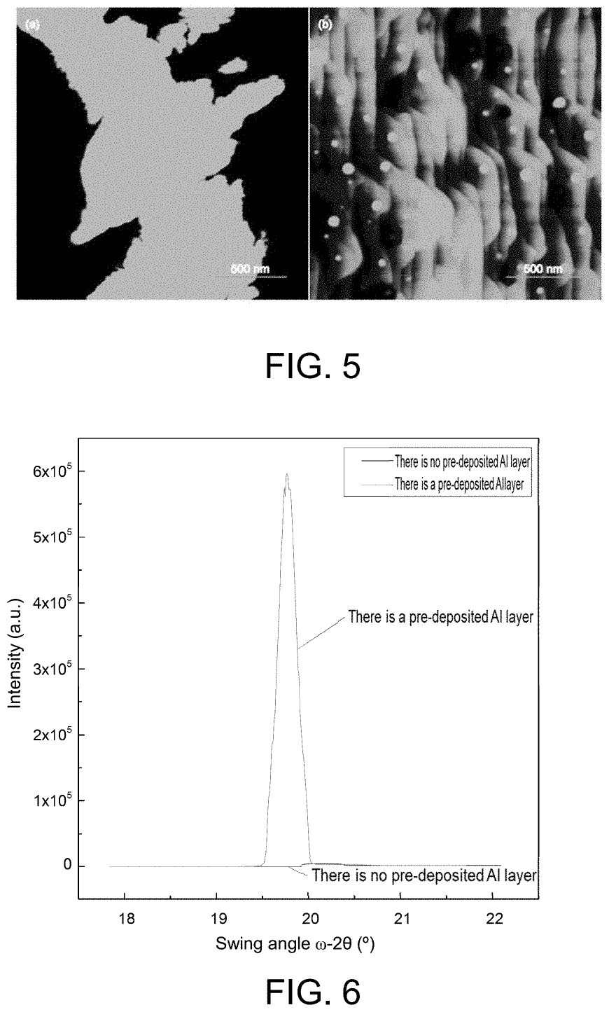

It was found (FIG. 5) through AFM observation that the GaN thin film grown by the conventional method had poor quality and could not obtain useful signals; while the GaN thin film grown by the optimization method was rough and uneven microscopically, and holes could be found.

It was found (FIG. 6) through XRD detection results that the GaN thin film grown by the conventional method could not obtain effective XRD data, which meant that the crystal quality was far below the GaN thin film grown by the optimization method.

To sum up, the new optimization method for epitaxial growth of an AlN thin film on a Si substrate could improve the homogeneity and surface quality of the GaN thin film grown thereon.

### EXAMPLE 3

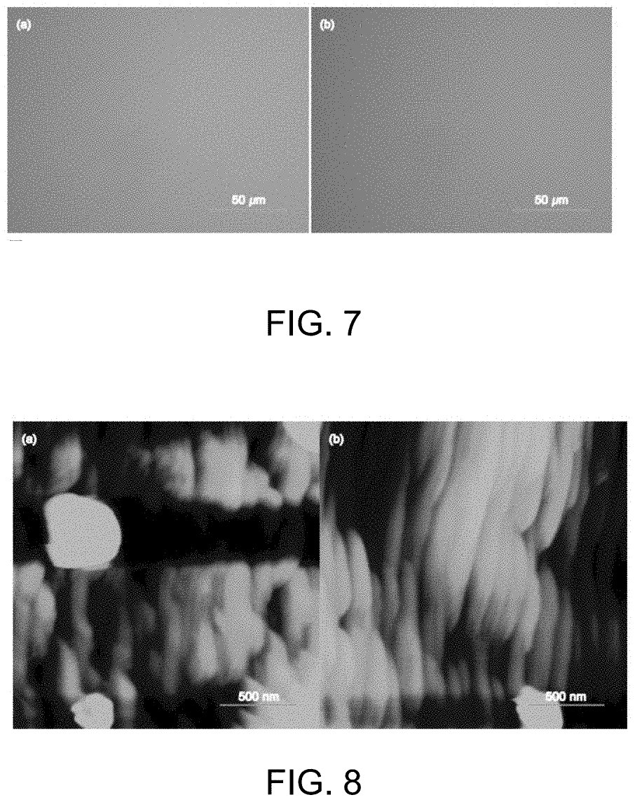

By referring to FIGS. 7-9, an AlGaN buffer layer and a GaN thin film were subjected to epitaxial growth on an AlN thin film, and the GaN thin film was represented and analyzed by OM, AFM and XRD, thus judging the effect of the optimization method.

A preparation method for growing AlGaN and GaN thin films on an AlN thin film has the following steps.

Step 1, growing an AlN epitaxial layer (growth parameters are common knowledge in the art, and thus are not specified any more) on a Si substrate: TMAl was fed as an Al source and NH₃ was fed as a N source under the condition that the reaction chamber was filled with H₂.

Step 2, pre-depositing a Ga atomic layer: the AlN thin film was put to a chamber, TMGa was fed as a Ga source under the condition that the reaction chamber was filled with H₂; where a surface temperature of AlN was controlled within a range from 800° C. to 1400° C., a reaction chamber pressure was controlled within a range from 20 mbar to 200 mbar; and time was controlled within a range from 0 s to 300 s, thus obtaining a pre-deposited Ga atomic layer. The pre-deposited Ga atomic layer might be adsorbed on the AlN thin film to form AlGaN nucleation sites.

Step 3, growing an AlGaN buffer layer (growth parameters are common knowledge in the art, and thus are not specified any more): TMAl was fed as an Al source, TMGa was fed as a Ga source, and NH₃ was fed as a N source under the condition that the reaction chamber was filled with H₂. During such process, the pre-deposited AlGaN nucleation sites grew up, thus forming an AlGaN thin film. During such growing process, the pre-deposited Ga layer disappeared and became a portion of the AlGaN thin film.

Step 4, growing a GaN epitaxial layer (growth parameters are common knowledge in the art, and thus are not specified any more): TMGa was fed as a Ga source and NH₃ was fed as a N source under the condition that the reaction chamber was filled with H₂.

The present invention was further proved by contrastive analysis on the conventional method and optimization method to have the following beneficial effects:

After an AlGaN buffer layer was grown by two methods of a conventional method (a pre-deposited Ga atomic layer was not taken) and an optimization method (a pre-deposited Ga atomic layer was taken), by making a comparison to the GaN thin films grown thereon, it was found that the AlGaN buffer layer prepared by the optimization method greatly improved the homogeneity and crystallization quality of the GaN thin film thereon.

It was found (FIG. 7) through OM observation that the GaN thin film grown by the conventional method had relatively dense cracks; while the GaN thin film grown by the optimization method had far fewer cracks.

It was found (FIG. 8) through AFM observation that the GaN thin film grown by the conventional method was rough and uneven, and had obvious cracks and holes; while the GaN thin film grown by the optimization method was rough and uneven microscopically, and precious little holes could be found.

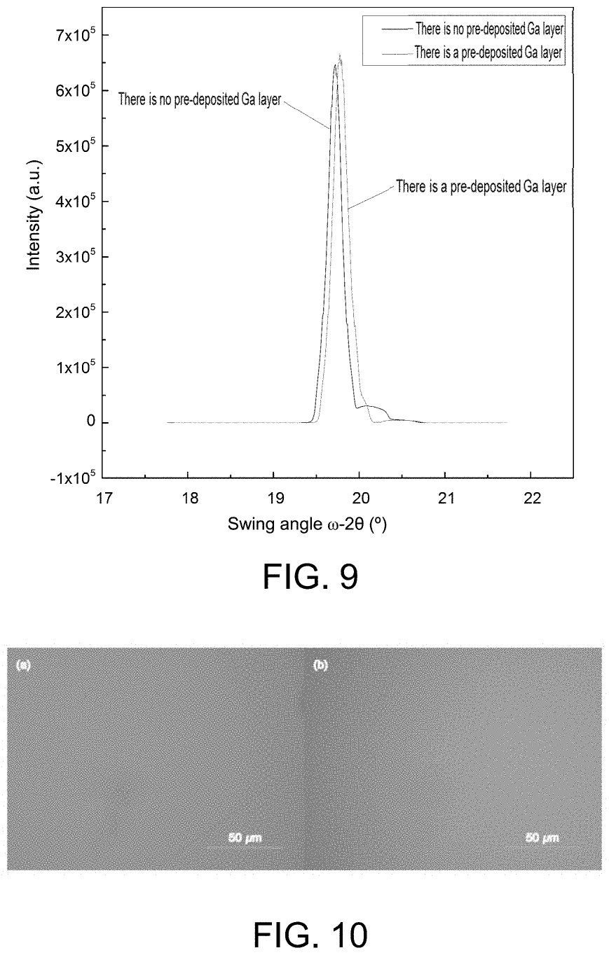

It was found (FIG. 9) through XRD detection results that peak intensity of the two methods was very close; that is, the crystal quality of the GaN thin film grown by the conventional method was slightly lower than that of the GaN thin film grown by the optimization method, but both had been very close.

To sum up, the new optimization method for epitaxial growth of an AlGaN thin film on an AlN thin film could improve the homogeneity and surface quality of the GaN thin film grown thereon.

### EXAMPLE 4

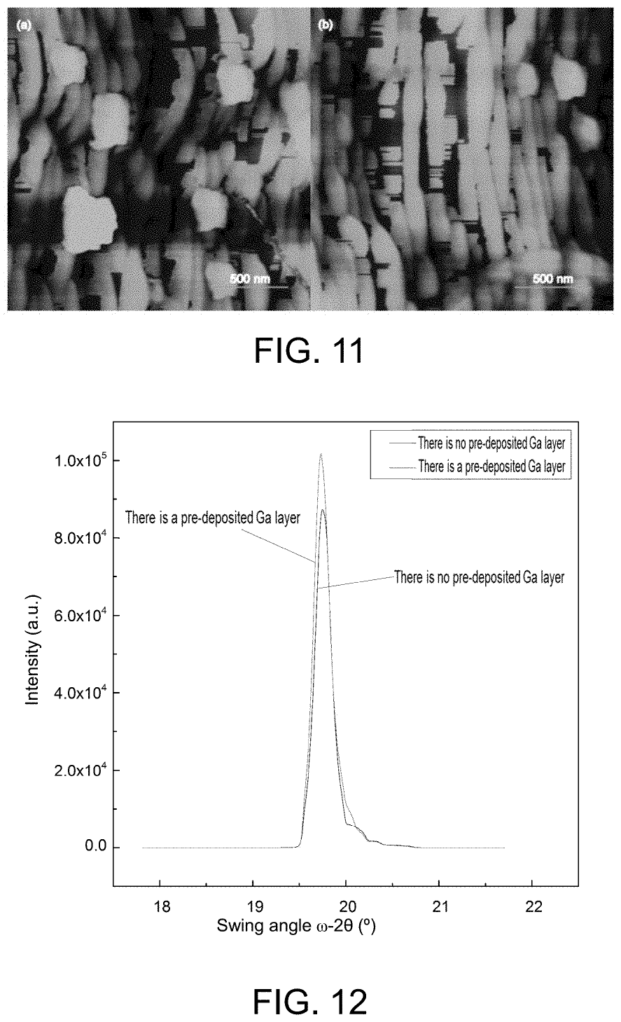

By referring to FIGS. 10-11, an Al_{y}Ga_{1-y}N buffer layer and a GaN thin film were subjected to epitaxial growth of on an AlₓGa₁₋ₓN thin film, where 1>x>y>0, such that the thin film gradually contained more Ga from containing less Ga. In this case, x=0.45 and y=0.25. Effect analysis was performed by using influences of a GaN thin film on the optimization method.

A preparation method for growing an Al_{0.25}Ga_{0.75}N and GaN thin films on an Al_{0.45}Ga_{0.55}N thin film has the following steps.

Step 1, growing AlN and Al_{0.45}Ga_{0.55}N epitaxial layers on a Si substrate (growth parameters are common knowledge in the art, and thus are not specified any more): TMAl was fed as an Al source, TMGa as a Ga source, and NH₃ was fed as a N source under the condition that the reaction chamber is filled with H₂.

Step 2, pre-depositing a Ga atomic layer: the Al_{0.45}Ga_{0.55}N thin film was put to a chamber, TMGa was fed as a Ga source under the condition that the reaction chamber was filled with H₂; where a surface temperature of Al_{0.45}Ga_{0.55}N was controlled within a range from 800° C. to 1400° C., a reaction chamber pressure was controlled within a range from 20 mbar to 200 mbar; and time was controlled within a range from 0 s to 300 s, thus obtaining a pre-deposited Ga atomic layer. The pre-deposited Ga atomic layer might be adsorbed on the Al_{0.45}Ga_{0.55}N thin film, rendering the component thereof to be gradually close to Al_{0.25}Ga_{0.75}N.

Step 3, growing an Al_{0.25}Ga_{0.75}N buffer layer (growth parameters are common knowledge in the art, and thus are not specified any more): TMAl was fed as an Al source, TMGa was fed as a Ga source and NH₃ was fed as a N source under the condition that the reaction chamber was filled with H₂. During such process, the surface of the Al_{0.45}Ga_{0.55}N thin film contained more and more Ga; therefore, the component thereof is closer and closer to Al_{0.25}Ga_{0.75}N, thus finally forming a stable Al_{0.25}Ga_{0.75}N thin film. During such growing process, the pre-deposited Ga layer disappeared and became a transition portion of the two thin films of Al_{0.45}Ga_{0.55}N and Al_{0.25}Ga_{0.75}N.

Step 4, growing a GaN epitaxial layer (growth parameters are common knowledge in the art, and thus are not specified any more): TMGa was fed as a Ga source and NH₃ was fed as a N source under the condition that the reaction chamber was filled with H₂.

The present invention was further proved by contrastive analysis on the conventional method and optimization method to have the following beneficial effects below.

After a high-component Al_{0.25}Ga_{0.75}N buffer layer was grown on a low-component Al_{0.45}Ga_{0.55}N by two methods of a conventional method (a pre-deposited Ga atomic layer was not taken) and an optimization method (a pre-deposited Ga atomic layer was taken), by making a comparison to the GaN thin films grown thereon, it was found that the Al_{0.25}Ga_{0.75}N buffer layer prepared by the optimization method greatly improved the homogeneity and crystallization quality of the GaN thin film thereon.

It was found (FIG. 9) through XRD detection results that the GaN thin film grown by the conventional method had crystal quality inferior to the GaN thin film grown by the optimization method.

It was found (FIG. 10) through OM observation that the GaN thin film grown by the conventional method had a little cracks; while no crack was found on the GaN thin film grown by the optimization method.

It was found (FIG. 11) through AFM observation that the GaN thin film grown by the conventional method was rough and uneven, a little holes could be found; while the GaN thin film grown by the optimization method was rough and uneven microscopically, and precious little holes could be found.

It was found (FIG. 12) through XRD detection results that the GaN thin film grown by the optimization method has a slightly higher peak intensity, that is, the crystal quality was higher than that of the GaN thin film grown by the conventional method.

To sum up, the new optimization method for epitaxial growth of a high-component AlGaN thin film on a low-component AlGaN thin film could improve the homogeneity and surface quality of the GaN thin film grown thereon.

### EXAMPLE 5

By referring to FIG. 12-15, a preparation method for epitaxial growth of a GaN thin film on an AlGaN thin film has the following steps.

Step 1, growing AlN and AlGaN epitaxial layers on a Si substrate (growth parameters are common knowledge in the art, and thus are not specified any more): TMAl was fed as an Al source, TMGa as a Ga source, and NH₃ was fed as a N source under the condition that the reaction chamber is filled with H₂.

Step 2, pre-depositing a Ga atomic layer: the AlGaN thin film was put to a chamber, TMGa was fed as a Ga source under the condition that the reaction chamber was filled with H₂; where a surface temperature of AlGaN was controlled within a range from 800° C. to 1400° C., a reaction chamber pressure was controlled within a range from 20 mbar to 200 mbar; and time was controlled within a range from 0 s to 300 s, thus obtaining a pre-paved Ga atomic layer. The pre-paved Ga atomic layer might be adsorbed on the AlGaN thin film to form an AlGaN atomic layer with a higher component and reach a saturation point rapidly, thus abstracting N atoms and forming GaN nucleation sites.

Step 3, growing a GaN buffer layer (growth parameters are common knowledge in the art, and thus are not specified any more): TMGa was fed as a Ga source and NH₃ was fed as a N source under the condition that the reaction chamber was filled with H₂. During such process, the pre-paved GaN nucleation sites grew up, thus forming a GaN thin film. During such growing process, the pre-paved Ga layer disappeared and became a portion of the GaN thin film.

The present invention was further proved by contrastive analysis on the conventional method and optimization method to have the following beneficial effects below.

After a GaN buffer layer was grown by two methods of a conventional method (a pre-deposited Ga atomic layer was not taken) and an optimization method (a pre-deposited Ga atomic layer was taken), by making a comparison to the GaN thin film, it was found that the GaN thin film prepared by the optimization method had improved homogeneity and crystal quality.

It was found (FIG. 12) through XRD detection results that the GaN thin film grown by the conventional method had crystal quality inferior to the GaN thin film grown by the optimization method.

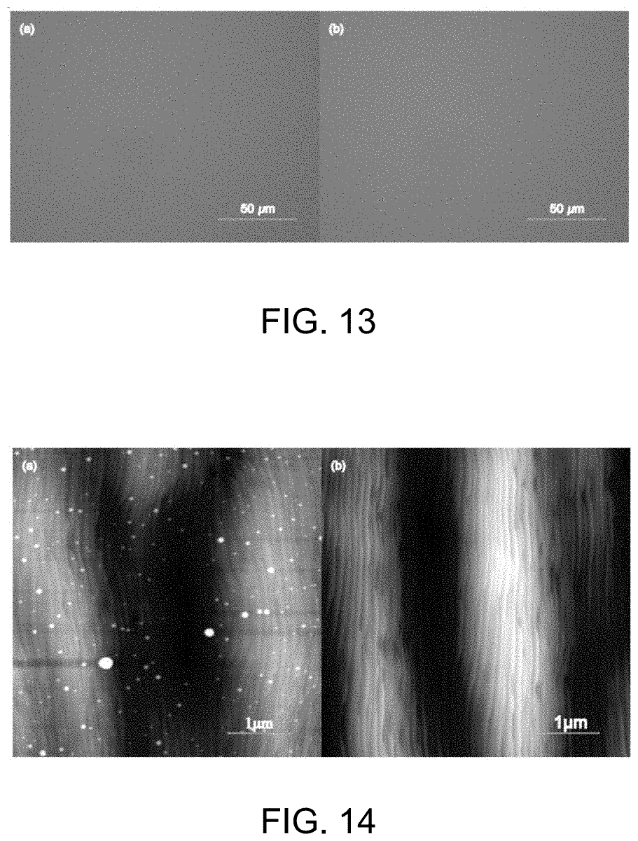

It was found (FIG. 13) through OM observation that no crack was found on the GaN thin film grown both by the conventional method and the optimization method.

It was found (FIG. 14) through AFM observation that no holes were found on GaN thin film both grown by the conventional method and the optimization method; but the GaN thin film grown by the optimization method had neater and longer grains.

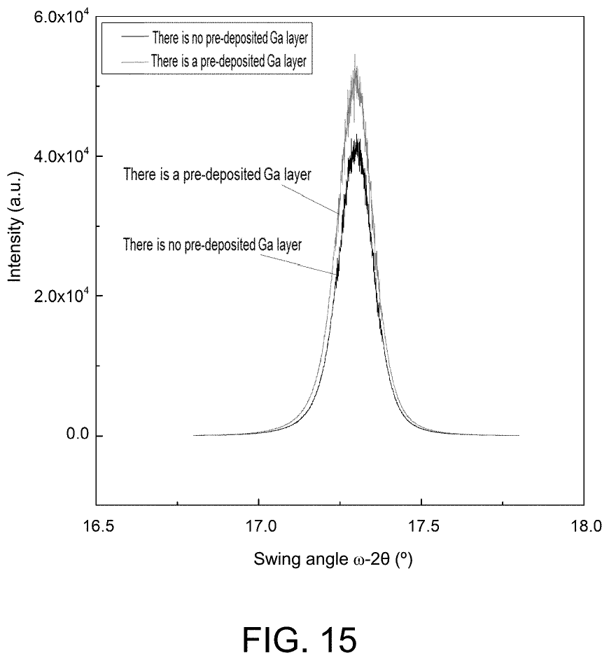

XRD detection results (FIG. 15) showed that the GaN thin film grown by the optimization method had a slightly higher peak intensity, that is, the crystal quality was higher than that of the GaN thin film grown by the conventional method.

To sum up, the new optimization method for epitaxial growth of a GaN thin film on an AlGaN thin film could improve the homogeneity and surface quality.

What is mentioned above is construed as limiting the prevent invention in any form; the prevent invention has been disclosed above by the preferred embodiments, but is not used to limit the present invention. A person skilled in the art can make some alterations or embellishments as equivalent embodiments by means of the structures and technical contents disclosed above within the scope of the technical solution of the present invention. Moreover, any simple modification or equivalent variation and embellishment made to the above examples based on the technical spirit of the present invention within the technical solution of the present invention shall fall within the scope of the technical solution of the present invention.

What is claimed is:

1. An optimizing growth method for improving quality of an MOCVD epitaxial thin film, comprising the following steps:
step 1, putting a substrate and a thin film A to a reaction chamber of an MOCVD equipment;
and feeding a compound containing an element X as an X source under the condition that the reaction chamber is filled with H₂; configuring a temperature, reaction chamber pressure and deposition time within a parameter range where the gaseous compound is capable of decomposing X atoms; pre-depositing an X atomic layer on a surface of the substrate or the thin film A, wherein the X atomic layer is adsorbed on the substrate or thin film A at this time; and the X atomic layer is reacted with other compounds to generate a thin film B component in the follow-up process, or is directly form a thin film B component with the thin film A; and
step 2, after completing the growth of the above pre-deposited X atomic layer, and subjecting the thin film B to growth; simultaneously feeding all gaseous compounds required by epitaxial growth of the thin film B under the condition that the reaction chamber is filled with H₂; configuring a temperature, reaction chamber pressure and deposition time within a parameter range capable of achieving epitaxial growth of the thin film B; subjecting the thin film B to epitaxial growth on the X atomic layer, wherein the pre-deposited X atomic layer is firstly reacted with the gas during such process, thus providing nucleation sites for the thin film B, and then the thin film B grows up with these nucleation sites as starting points; or wherein the pre-deposited X atomic layer has generated the thin film B component with the thin film A as nucleation sites; and at this time, the thin film B grows up with these nucleation sites as starting points; during such growing process, the pre-deposited X atomic layer disappears and becomes a portion of the thin film B.

2. The optimizing growth method according to claim 1, wherein in the step 1, the temperature is controlled within a range from 800° C. to 1400° C.; the reaction chamber pressure is controlled within a range from 20 mbar to 200 mbar; and the time is controlled within a range from 0 s to 300 s.

3. The optimizing growth method according to claim 1, wherein,
subjecting an AlN buffer layer and a GaN thin film to epitaxial growth on a Si substrate, comprising the following preparation method:
(1) pretreating the Si substrate, comprising a cleaning process and a desorption process;
(2) pre-depositing an Al atomic layer, putting the Si substrate to a reaction chamber of a MOCVD equipment, feeding TMAl as an Al source under the condition that the reaction chamber is filled with H₂; wherein a surface temperature of the Si substrate is controlled within a range from 800° C. to 1400° C., a reaction chamber pressure is controlled within a range from 20 mbar to 200 mbar; and time is controlled within a range from 0 s to 300 s, thus obtaining a pre-deposited Al atomic layer, wherein the pre-deposited Al atomic layer is adsorbed on the Si substrate;
(3) growing the AlN buffer layer, feeding TMAl as an Al source and feeding NH₃ as a N source under the condition that the reaction chamber is filled with H₂; wherein during such process, the pre-deposited Al atomic layer is firstly reacted with NH₃ to form AlN nucleation sites, then AlN nucleation sites grow up to thereby forming an AlN thin film, and during such growing process, the pre-deposited Al atomic layer disappears and becomes a portion of the AlN thin film; and
(4) growing a GaN epitaxial layer, feeding TMGa as a Ga source and feeding NH₃ as a N source under the condition that the reaction chamber is filled with H₂.

4. The optimizing growth method according to claim 1, wherein,
subjecting an AlGaN buffer layer and a GaN thin film to epitaxial growth on an AlN thin film, comprising the following preparation method:
(1) growing an AlN epitaxial layer on a Si substrate, feeding TMAl as an Al source and feeding NH₃ as a N source under the condition that the reaction chamber is filled with H₂;
(2) pre-depositing a Ga atomic layer, putting an AlN thin film to a chamber, feeding TMGa as a Ga source under the condition that the reaction chamber is filled with H₂; wherein a surface temperature of AlN is controlled within a range from 800° C. to 1400° C., a reaction chamber pressure is controlled within a range from 20 mbar to 200 mbar; and time is controlled within a range from 0 s to 300 s, thus obtaining a pre-deposited Ga atomic layer, wherein the pre-deposited Ga atomic layer is adsorbed on the AlN thin film to form AlGaN nucleation sites;
(3) growing the AlGaN buffer layer, feeding TMAl as an Al source, feeding TMGa as a Ga source, and feeding NH₃ as a N source under the condition that the reaction chamber is filled with H₂; wherein during such process, the pre-deposited AlGaN nucleation sites grow up to thereby forming an AlGaN thin film, and during such growing process, the pre-deposited Ga atomic layer disappears and becomes a portion of the AlGaN thin film; and
(4) growing a GaN epitaxial layer, feeding TMGa as a Ga source and feeding NH₃ as a N source under the condition that the reaction chamber is filled with H₂.

5. The optimizing growth method according to claim 1, wherein, subjecting an Al_{y}Ga_{1-y}N buffer layer and a GaN thin film to epitaxial growth on an AlₓGa₁₋ₓN thin film, comprising the following preparation method, wherein 1>x>y>0:
(1) growing an AlN and Al_{0.45}Ga_{0.55}N epitaxial layers on a Si substrate, feeding TMAl as an Al source, feeding TMGa as a Ga source, and feeding NH₃ as a N source under the condition that the reaction chamber is filled with H₂;
(2) pre-depositing a Ga atomic layer, putting the Al_{0.45}Ga_{0.55}N thin film to a chamber, feeding TMGa as a Ga source under the condition that the reaction chamber is filled with H₂; wherein a surface temperature of Al_{0.45}Ga_{0.55}N is controlled within a range from 800° C. to 1400° C., a reaction chamber pressure is controlled within a range from 20 mbar to 200 mbar; and time is controlled within a range from 0 s to 300 s, thus obtaining a pre-deposited Ga atomic layer; wherein the pre-deposited Ga atomic layer can be adsorbed on the Al_{0.45}Ga_{0.55}N thin film, thus rendering the components thereof to be gradually close to an Al_{0.25}Ga_{0.75}N-grown thin film;
(3) growing an Al_{0.25}Ga_{0.75}N buffer layer, feeding TMAl as an Al source, feeding TMGa as a Ga source and feeding NH₃ as a N source under the condition that the reaction chamber is filled with H₂; during such process, a surface of the Al_{0.45}Ga_{0.55}N thin film contains more and more Ga component, such that the components thereof are closer and closer to the Al_{0.25}Ga_{0.75}N-grown thin film, thereby finally forming a stable Al_{0.25}Ga_{0.75}N-grown thin film; wherein during such growing process, the pre-deposited Ga atomic layer disappears and becomes a transition portion grown with two thin films of Al_{0.45}Ga_{0.55}N and Al_{0.25}Ga_{0.75}N; and
(4) growing a GaN epitaxial layer, feeding TMGa as a Ga source and feeding NH3 as a N source under the condition that the reaction chamber is filled with H₂.

6. The optimizing growth method according to claim 1, wherein,
subjecting a GaN thin film to epitaxial growth on an AlGaN thin film, comprising the following preparation method:
(1) growing AlN and AlGaN epitaxial layers on a Si substrate, feeding TMAl as an Al source, feeding TMGa as a Ga source, and feeding NH₃ as a N source under the condition that the reaction chamber is filled with H₂;
(2) pre-depositing a Ga atomic layer, putting an AlGaN thin film to a chamber, feeding TMGa as a Ga source under the condition that the reaction chamber is filled with H₂; wherein a surface temperature of AlGaN is controlled within a range from 800° C. to 1400° C., a reaction chamber pressure is controlled within a range from 20 mbar to 200 mbar; and time is controlled within a range from 0 s to 300 s; wherein the pre-deposited Ga atomic layer can be adsorbed on the AlGaN thin film to form an AlGaN atomic layer with a higher component and reach a saturation point rapidly, thereby abstracting N atoms and forming GaN nucleation sites; and
(3) growing a GaN buffer layer, feeding TMGa as a Ga source, and feeding NH₃ as a N source under the condition that the reaction chamber is filled with H₂; wherein during such process, the pre-deposited GaN nucleation sites grow up, thereby forming a GaN thin film, and during such growing process, the pre-deposited Ga atomic layer disappears and becomes a portion of the GaN thin film.

7. The optimizing growth method according to claim 2, wherein,
subjecting an AlN buffer layer and a GaN thin film to epitaxial growth on a Si substrate, comprising the following preparation method:
(1) pretreating the Si substrate, comprising a cleaning process and a desorption process;
(2) pre-depositing an Al atomic layer, putting the Si substrate to a reaction chamber of a MOCVD equipment, feeding TMAl as an Al source under the condition that the reaction chamber is filled with H₂; wherein a surface temperature of the Si substrate is controlled within a range from 800° C. to 1400° C., a reaction chamber pressure is controlled within a range from 20 mbar to 200 mbar; and time is controlled within a range from 0 s to 300 s, thus obtaining a pre-deposited Al atomic layer, wherein the pre-deposited Al atomic layer is adsorbed on the Si substrate;
(3) growing the AlN buffer layer, feeding TMAl as an Al source and feeding NH₃ as a N source under the condition that the reaction chamber is filled with H₂; wherein during such process, the pre-deposited Al atomic layer is firstly reacted with NH₃ to form AlN nucleation sites, then AlN nucleation sites grow up to thereby forming an AlN thin film, and during such growing process, the pre-deposited Al atomic layer disappears and becomes a portion of the AlN thin film; and
(4) growing a GaN epitaxial layer, feeding TMGa as a Ga source and feeding NH₃ as a N source under the condition that the reaction chamber is filled with H₂.

8. The optimizing growth method according to claim 2, wherein,
subjecting an AlGaN buffer layer and a GaN thin film to epitaxial growth on an AlN thin film, comprising the following preparation method:
(1) growing an AlN epitaxial layer on a Si substrate, feeding TMAl as an Al source and feeding NH₃ as a N source under the condition that the reaction chamber is filled with H₂;
(2) pre-depositing a Ga atomic layer, putting an AlN thin film to a chamber, feeding TMGa as a Ga source under the condition that the reaction chamber is filled with H₂; wherein a surface temperature of AlN is controlled within a range from 800° C. to 1400° C., a reaction chamber pressure is controlled within a range from 20 mbar to 200 mbar; and time is controlled within a range from 0 s to 300 s, thus obtaining a pre-deposited Ga atomic layer, wherein the pre-deposited Ga atomic layer is adsorbed on the AlN thin film to form AlGaN nucleation sites;
(3) growing the AlGaN buffer layer, feeding TMAl as an Al source, feeding TMGa as a Ga source, and feeding NH₃ as a N source under the condition that the reaction chamber is filled with H₂; wherein during such process, the pre-deposited AlGaN nucleation sites grow up to thereby forming an AlGaN thin film, and during such growing process, the pre-deposited Ga atomic layer disappears and becomes a portion of the AlGaN thin film; and
(4) growing a GaN epitaxial layer, feeding TMGa as a Ga source and feeding NH₃ as a N source under the condition that the reaction chamber is filled with H₂.

9. The optimizing growth method according to claim 2, wherein,
subjecting an Al_{y}Ga_{1-y}N buffer layer and a GaN thin film to epitaxial growth on an AlₓGa₁₋ₓN thin film, comprising the following preparation method, wherein 1>x>y>0:
(1) growing an AlN and Al_{0.45}Ga_{0.55}N epitaxial layers on a Si substrate, feeding TMAl as an Al source, feeding TMGa as a Ga source, and feeding NH₃ as a N source under the condition that the reaction chamber is filled with H₂;
(2) pre-depositing a Ga atomic layer, putting the Al_{0.45}Ga_{0.55}N thin film to a chamber, feeding TMGa as a Ga source under the condition that the reaction chamber is filled with H₂; wherein a surface temperature of Al_{0.45}Ga_{0.55}N is controlled within a range from 800° C. to 1400° C., a reaction chamber pressure is controlled within a range from 20 mbar to 200 mbar; and time is controlled within a range from 0 s to 300 s, thus obtaining a pre-deposited Ga atomic layer; wherein the pre-deposited Ga atomic layer can be adsorbed on the Al_{0.45}Ga_{0.55}N thin film, thus rendering the components thereof to be gradually close to an Al_{0.25}Ga_{0.75}N-grown thin film;
(3) growing an Al_{0.25}Ga_{0.75}N buffer layer, feeding TMAl as an Al source, feeding TMGa as a Ga source and feeding NH₃ as a N source under the condition that the reaction chamber is filled with H₂; during such process, a surface of the Al_{0.45}Ga_{0.55}N thin film contains more and more Ga component, such that the components thereof are closer and closer to the Al_{0.25}Ga_{0.75}N-grown thin film, thereby finally forming a stable Al_{0.25}Ga_{0.75}N-grown thin film; wherein during such growing process, the pre-deposited Ga atomic layer disappears and becomes a transition portion grown with two thin films of Al_{0.45}Ga_{0.55}N and Al_{0.25}Ga_{0.75}N; and
(4) growing a GaN epitaxial layer, feeding TMGa as a Ga source and feeding NH3 as a N source under the condition that the reaction chamber is filled with H₂.

10. The optimizing growth method according to claim 2, wherein,
subjecting a GaN thin film to epitaxial growth on an AlGaN thin film, comprising the following preparation method:
(1) growing AlN and AlGaN epitaxial layers on a Si substrate, feeding TMAl as an Al source, feeding TMGa as a Ga source, and feeding NH₃ as a N source under the condition that the reaction chamber is filled with H₂;
(2) pre-depositing a Ga atomic layer, putting an AlGaN thin film to a chamber, feeding TMGa as a Ga source under the condition that the reaction chamber is filled with H₂; wherein a surface temperature of AlGaN is controlled within a range from 800° C. to 1400° C., a reaction chamber pressure is controlled within a range from 20 mbar to 200 mbar; and time is controlled within a range from 0 s to 300 s; wherein the pre-deposited Ga atomic layer can be adsorbed on the AlGaN thin film to form an AlGaN atomic layer with a higher component and reach a saturation point rapidly, thereby abstracting N atoms and forming GaN nucleation sites; and
(3) growing a GaN buffer layer, feeding TMGa as a Ga source, and feeding NH₃ as a N source under the condition that the reaction chamber is filled with H₂; wherein during such process, the pre-deposited GaN nucleation sites grow up, thereby forming a GaN thin film, and during such growing process, the pre-deposited Ga atomic layer disappears and becomes a portion of the GaN thin film.
